(19) United States
(12) Patent Application Publication
(10) Pub. No.: US 2024/0157431 A1
(43) Pub. Date: May 16, 2024

(54) METHOD FOR MAKING NON-SPHERICAL SOLDER BALL

(71) Applicant: JOINSET CO., LTD., Ansan-si (KR)

(72) Inventor: Sun-Ki Kim, Gunpo-si (KR)

(21) Appl. No.: 18/232,495

(22) Filed: Aug. 10, 2023

(30) Foreign Application Priority Data
Aug. 11, 2022 (KR) 10-2022-0100485

(51) Int. Cl. B21K 23/00; B21K 29/00

(52) U.S. Cl. CPC B21K 23/00; B21K 29/00

(57) ABSTRACT

Disclosed is a making method for mass-producing non-spherical solder balls. The making method includes: inserting spherical solder balls into non-spherical accommodation grooves; melting the spherical solder balls by heating and filling the accommodation grooves with the molten solder; making non-spherical solder balls by cooling the molten solder; and withdrawing the non-spherical solder balls from the accommodation grooves.

### REFERENCE TO RELATED APPLICATIONS

This application claims the priority benefit of Korean Patent Application No. 10-2022-0100485 filed on Aug. 11, 2022, the entire contents of which are incorporated herein by reference.

### FIELD OF THE INVENTION

The present disclosure relates to a method for making a non-spherical solder ball, and more particularly, to a technique of mass-producing a non-spherical solder ball efficiently, uniformly, and economically.

### BACKGROUND OF THE INVENTION

A ball grid array (BGA) method may be applied to mount a semiconductor on a circuit board, and in this case, a spherical solder ball is applied to mechanically bond and electrically connect the semiconductor to the circuit board.

Materials and technologies for making the above-described spherical solder ball are well-known.

Referring to an embodiment of a method for making the spherical solder ball, the spherical solder ball having a constant size is manufactured by melting a solder alloy in molten metal, injecting a master alloy and then performing induction heating, and allowing the solder alloy to pass through an orifice hole.

For example, the spherical solder ball is manufactured by performing a process of using a solder alloy containing 40 wt % to 60 wt % of bismuth (Bi), 0.1 wt % to 3.0 wt % of silver (Ag), 0.3 wt % to 1.0 wt % of copper (Cu), and the rest of tin (Sn).

As another making method, a spherical solder ball having a predetermined size is manufactured by allowing a molten solder alloy to be freely dropped by vibration of ultrasonic waves onto a rotating circular plate disposed therebelow and then cooling the dropped solder alloy, and then the spherical solder balls are sorted to a certain size.

According to the above-described making method, the spherical solder ball having the constant size may be efficiently and economically mass-produced.

However, since conventional spherical solder balls have the same diameter, maximum width, and maximum height, the conventional spherical solder balls have a limitation when applied to semiconductor packaging or an electronic component assembly that has a great height and a narrow width.

Due to the above-described reason, when the solder ball having a hemispherical or hexahedral shape is required instead of the spherical solder ball, another method for cutting a solder alloy sheet may be used instead of using the conventional making method.

When the solder ball having the hexahedral shape is manufactured, the solder ball may be manufactured by cutting a solder alloy sheet having a constant thickness using a dicing saw or a press mold. However, the solder alloy sheet having the constant thickness is inconvenient to be provided, has low hardness and low productivity, and easily generates a burr at a cut portion.

Also, when the solder ball is manufactured by using a mold, a molten solder alloy is required to be manufactured by inserting the molten solder alloy with a fixed amount and time into a mold frame having hexahedral accommodation grooves. However, the hexahedral solder ball having a reliable uniform shape and size is difficult to be economically provided due to a viscosity and temperature of the molten solder alloy and a shape and temperature of a mold frame.

Also, production efficiency is deteriorated, or production quality is not constant because the solder ball is an extremely small, has a precise size, and is provided with large amount although a predetermined amount of solder alloy melted in the mold frame having the plurality of accommodation grooves is pressed and discharged by using a precision dispenser.

### SUMMARY OF THE INVENTION

The present disclosure provides a making method for mass-producing non-spherical solder balls efficiently, uniformly, and economically.

The present disclosure also provides a making method for easily making non-spherical solder balls having the same size and shape as each other within a range that is not deviated from a deviation during mass production.

An embodiment of the present disclosure provides a method for making a non-spherical solder ball that mechanically and electrically connects an object by soldering, the method including: preparing a plurality of spherical solder balls; preparing a mold having a plurality of non-spherical accommodation grooves; inserting the spherical solder balls into the non-spherical accommodation grooves; deforming the spherical solder balls into a shape corresponding to that of each of the non-spherical accommodation grooves and making non-spherical solder balls by applying heat, pressure, or a combination thereof to the spherical solder balls or the mold in the state in which the spherical solder balls are inserted into the non-spherical accommodation grooves; withdrawing the non-spherical solder balls from the non-spherical accommodation grooves; and sorting the withdrawn non-spherical solder balls according to a preset reference.

In an embodiment, the non-spherical solder ball has a shape formed only by a shape of the non-spherical accommodation groove or formed by combining the shape of the non-spherical accommodation groove with a shape of a cover configured to cover the mold.

In an embodiment, each of the mold and the cover may be made of a metal material or a heat-resistant polymer material that is not attached to the non-spherical solder ball when the non-spherical solder ball is manufactured by the heating.

In an embodiment, the spherical solder ball melted by the heating is deformed by ultrasonic waves, vibration of a motor, or a pressure by the cover.

In an embodiment, the heating is performed at a temperature at which the spherical solder ball is softened or melted.

In an embodiment, the method may further include cooling the non-spherical solder ball when making the non-spherical solder ball by the heating.

In an embodiment, the non-spherical solder ball is symmetrical in an upward and downward direction and a left and right direction, and at least one surface of surfaces of the non-spherical solder ball forms a plane.

In an embodiment, the non-spherical solder ball may have a hemispherical, cylindrical or hexahedral shape different from that of the spherical solder ball.

In an embodiment of the present disclosure, a method for making a non-spherical solder ball that mechanically and electrically connect an object by soldering includes: inserting a spherical solder ball having a structure in which a solder or solder alloy is laminated on a spherical metal or polymer core into a non-spherical accommodation groove of an instrument; deforming the spherical solder ball into a shape corresponding to that of the accommodation groove by applying physical force to the spherical solder ball; melting the solder or solder alloy by heating the deformed spherical solder ball; forming a non-spherical solder ball by cooling the melted solder or solder alloy; and withdrawing the cooled non-spherical solder ball and sorting the withdrawn non-spherical solder ball according to a preset reference.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain principles of the present disclosure. In the drawings:

FIGS. 1A to 1C are views schematically illustrating a method for making a non-spherical solder ball according to an embodiment of the present disclosure;

FIGS. 2A to 2C are views illustrating various shapes of the non-spherical solder ball;

FIG. 3 is a flowchart explaining the method for making the non-spherical solder ball;

FIGS. 4A and 4B are views schematically illustrating a method for making a non-spherical solder ball according to another embodiment of the present disclosure; and

FIGS. 5A to 5C are views schematically illustrating a method for making a non-spherical solder ball according to another embodiment of the present disclosure.

### DETAILED DESCRIPTION OF THE INVENTION

In the following description, the technical terms are used only for explain a specific exemplary embodiment while not limiting the present disclosure. Unless otherwise defined, all technical terms used herein have the same meaning as generally understood by those skilled in the art. Terms as defined in a commonly used dictionary should be construed as having the same meaning as in an associated technical context, and unless defined apparently in the description, the terms are not ideally or excessively construed as having formal meaning.

Hereinafter, specific embodiments of the present disclosure will be described in detail with reference to the accompanying drawings.

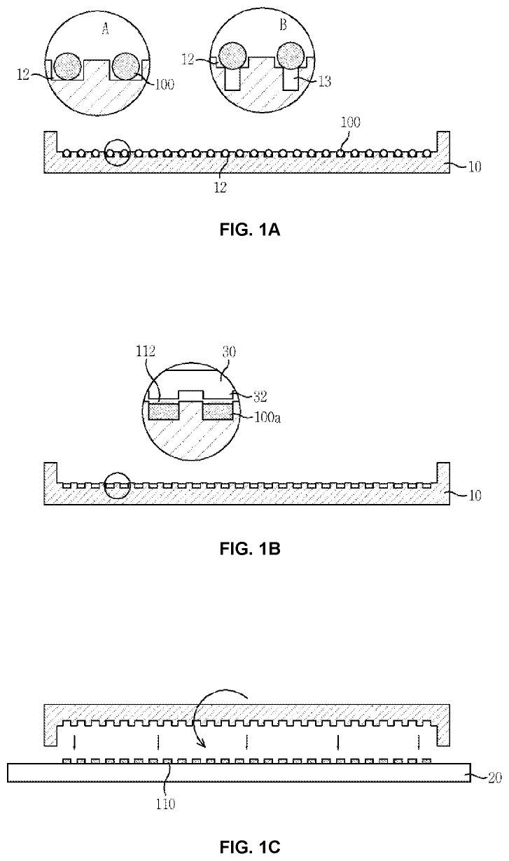

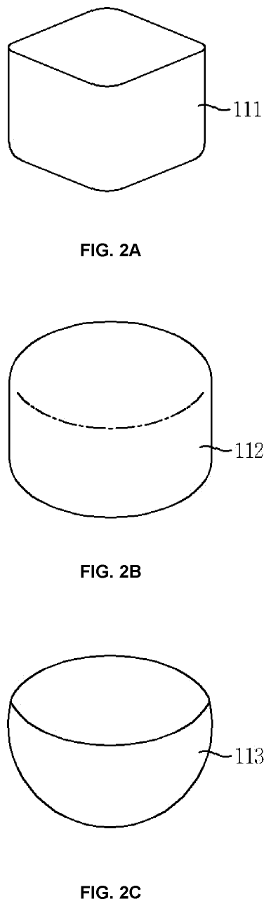

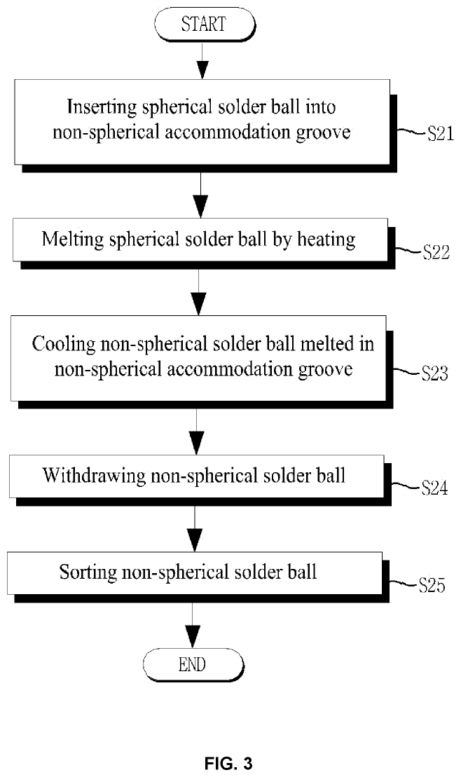

FIGS. 1A to 1C are views schematically illustrating a method for a making non-spherical ball according to an embodiment of the present disclosure, FIGS. 2A to 2C are views schematically illustrating various shapes of non-spherical balls, and FIG. 3 is a flowchart for explaining the method for making a non-spherical solder ball.

The solder ball serves to mechanically and electrically connect an electronic component such as a semiconductor or a metal cover and a circuit board by soldering. The solder ball is formed into a spherical solder ball 100 as illustrated in FIG. 1.

The above-described conventional spherical solder ball that is a key component of a semiconductor package technology such as ball grid array (BGA) or chip scale package (CSP) serves to connect a chip and a substrate and transmit an electrical signal. For example, the solder ball is manufactured and supplied by Senju Metal of Japan and Duksan Hi-Metal of the Republic of Korea.

Here, the conventional spherical solder ball 100 has an extremely precise spherical shape and dimension, i.e., a diameter of approximately 0.025 mm to approximately 0.9 mm, a diameter tolerance of approximately ±0.025 mm to approximately ±0.003 mm, and a Cpk of approximately 1.5 mm or more. The solder ball 100 is made of various solder alloy materials such as Sn-3.0Ag-0.5Cu or Sn-1.2Ag-0.5Cu-0.05Ni.

The present disclosure relates to a method for making a non-spherical solder ball by processing the above-described conventional spherical solder ball, which is uniform, economical, and currently commercially available. Thus, the non-spherical solder ball may be efficiently mass-produced with the same size and shape within a range that is not greatly deviated from deviations during the mass production.

That is, the present disclosure may make the non-spherical solder ball by using a simple, easy, and economic making method for producing the non-spherical solder ball with a uniform dimension, shape, and weight in comparison with the making method of producing the non-spherical solder ball using the solder alloy sheet or the liquid solder alloy by providing the non-spherical solder ball from the conventional spherical solder ball, which is in a solid phase and currently commercially available.

Although the conventional spherical solder ball 100 in the solid phase is made of only a solder alloy in an embodiment of FIG. 1, the embodiment of the present disclosure is not limited thereto.

Firstly, an instrument 10 having a flat surface in which a plurality of non-spherical accommodation grooves 12 are formed in a matrix form is prepared, and the manufactured spherical solder ball 100 are inserted into each of the accommodation grooves 12, e.g., one by one, in operation S21.

Although not shown, when a non-spherical solder ball having a desired size or shape is not obtained by using one spherical solder ball 100, the non-spherical solder ball having the desired size or shape may be manufactured by stacking or horizontally arranging two or more spherical solder balls 100 in one non-spherical accommodation groove 12.

For example, the non-spherical solder ball having a height, length, or width greater than a diameter of the spherical solder ball 100 may be manufactured by inserting two or more spherical solder balls 100 into one non-spherical accommodation groove 12 although a shape and a dimension of the non-spherical solder ball manufactured by using one spherical solder ball 100 are inevitably limited due to a predetermined diameter of the spherical solder ball 100.

The instrument 10 may be a metal mold, a ceramic substrate, or a base plate and made of a material resistant to heat and a pressure, which will be described later, e.g., a metal such as stainless steel or cemented carbide, ceramic such as an alumina substrate, or a polymer such as fluorine resin.

Preferably, the instrument 10 may be made of a metal material or a heat-resistant polymer material that is not soldered or attached to the non-spherical solder ball 110 when the non-spherical solder ball 110 is manufactured by melting the spherical solder ball 100.

Although the instrument 10 may be a single body in which a plurality of accommodation grooves 12 are integrated or a coupled body of a first instrument having a through-hole and a second instrument coupled to a bottom surface of the first instrument to block the through-hole.

The accommodation groove 12 may have various non-spherical shapes such as a half-moon shape, a cone shape, an egg shape, a pyramid shape, or a hexahedral shape instead of the spherical shape. Preferably, the accommodation groove 12 may have a greater height and a less width than the diameter of the spherical solder ball 100.

In this embodiment, as the accommodation groove 12 has a height less than a width thereof, the non-spherical solder ball 110 has a hexahedral shape having a height less than a width thereof. Thus, the non-spherical solder ball 110 having the height less than the width may correspond to packaging of a semiconductor chip having a micro-pattern.

Here, the height of the non-spherical solder ball 110 may represent a spaced distance between a semiconductor chip and a circuit board in a height direction.

Referring to an enlarged circle B of FIG. 1A, as a seat groove 12 allowing the spherical solder ball 100 to be accommodated and seated thereon and an accommodation groove 13 accommodating melted solder are separately provided, a width of the accommodation groove 13 is further reduced. As a result, the non-spherical solder ball 110 manufactured therefrom may have a reduced width and thus be applied to a micro-pattern.

Although the spherical solder ball 100 inserted into the accommodation groove 12 may have a volume equal to or less than that of the accommodation groove 12, the embodiment of the present disclosure is not limited thereto.

Preferably, the spherical solder ball 100 may be reliably and economically inserted into the accommodation groove 12 by ultrasonic waves or vibration of a motor, which are provided to the instrument 10.

Thereafter, the spherical solder ball 100 is melted by applying heat to the spherical solder ball 100, and a molten solder 100a is filled into the accommodation groove 12 as illustrated in FIG. 1B in operation S22.

Here, a method for applying heat to the spherical solder ball 100 may include a method for directly heating the spherical solder ball 100 inserted into the accommodation groove 12, a method for heating the instrument 10 in which the spherical solder ball 100 is inserted into the accommodation groove 12, or a method for melting the spherical solder ball 100 by inserting, into an oven or a furnace, the instrument 10 in which the spherical solder ball 100 is inserted into the accommodation groove 12.

Here, the spherical solder ball 100 may be heated by a laser, ultrasonic waves, a heater, an oven, or a heat treatment furnace.

Preferably, the heating temperature is a temperature at which the solid spherical solder ball 100 is converted into a liquid having physical flowability, and particularly, a temperature at which two or more spherical solder balls 100 are physically combined with each other, i.e., a melting temperature, when the two or more spherical solder balls 100 are inserted into one accommodation groove 12.

Preferably, the heating temperature is about 50° C. to about 230° C. depending on a material of the spherical solder ball 100. However, the embodiment of the present disclosure is not limited to the material of the spherical solder ball 100.

Preferably, when or after the spherical solder ball 100 is melted in the accommodation groove 12, the ultrasonic waves or vibration caused by the motor is provided to the instrument 10 so that the molten solder alloy easily corresponds to a shape of the accommodation groove 12.

In this embodiment, the shape of the non-spherical solder ball 110 may be formed by the shape of the accommodation groove 12. In addition, a shape of a groove or protrusion formed in a portion corresponding to the accommodation groove 12 in a cover 30 covering the instrument 10 may be added to the shape of the accommodation groove 12 to complete the shape of the non-spherical solder ball 110.

In this embodiment, since an amount of the molten solder 100a is less than a volume of the accommodation groove 12, a surface of the molten solder 100a is correspondingly positioned in the accommodation groove 12. However, the embodiment of the present disclosure is not limited thereto.

Thereafter, the molten solder 100a is cooled in operation S23.

Preferably, the surface of the molten solder 100a may be flattened by using the cover 30 covering a top surface of the instrument 10 in the process of cooling the molten solder 100a,

Specifically, referring to an enlarged circle of FIG. 1B, the surface of the molten solder 100a may form a gentle curved surface 112 as expressed by a dotted line due to surface tension in a process of curing the molten solder 100a by the cooling.

The surface of the molten solder 100a may be flattened by using a pressing protrusion 32 integrated with the cover 30 in considering that each of the surface and a rear surface of a bottom of the molten solder 100a are used to be in contact with an electrode.

Here, the cover 30 may be made of a metal material or a heat-resistant polymer material to which the molten solder 100a is not attached.

Referring to FIG. 1C, the non-spherical solder ball 110 cooled in the accommodation groove 12 is withdrawn from the accommodation groove 12 by turning the instrument 10 upside down and applying a predetermined impact thereto in operation S24.

Selectively, the withdrawn non-spherical solder ball 110 may remove a burr formed on an edge or allow the edge to be finely curved through barrel polishing or the like.

The non-spherical solder ball 110 withdrawn from the accommodation groove 12 has various shapes and preferably has a symmetrical shape in left/right and upward/downward directions in consideration of when the non-spherical solder ball 110 is substantially used in a semiconductor chip.

Thereafter, the withdrawn non-spherical solder ball 110 is sorted to have a required dimension and shape in operation S25.

The non-spherical solder ball 110 manufactured as described above may have various shapes in correspondence to the accommodation groove 12. For example, a non-spherical solder ball 111 of FIG. 2A may have a hexahedral shape having rounded sides, a non-spherical solder ball 112 of FIG. 2B may have a cylindrical shape having a low height, and a non-spherical solder ball 113 of FIG. 2C may have a hemispherical shape having a flat surface on a top or bottom surface. In addition, the non-spherical solder ball may have a conical, oval, or pyramidal shape. Preferably, the non-spherical solder ball may have a greater height and a less width than the diameter of the spherical solder ball 100.

Preferably, the non-spherical solder ball 110 may have a weight equal to that of the initially provided spherical solder ball 100.

Preferably, at least one surface of the surface of the non-spherical solder ball 110 is flat for stability during soldering and easy surface mounting for vacuum pickup.

The above-described making method may mass-produce uniformly and economically the non-spherical solder balls 110 by inserting the solid spherical solder ball 100 that is previously manufactured uniformly and economically into the accommodation groove 12 and then melting the spherical solder ball 100 to make the non-spherical solder balls 110, so that the non-spherical solder ball 110 easily has a uniform size and shape within a range that is not greatly deviated from deviations during the mass production.

For example, the non-spherical solder ball 110 may be reel-packed in a reel carrier pocket. The pocket may have a shape corresponding to that of the non-spherical solder ball so that the non-spherical solder ball 110 may be stably reel-packed and have a predetermined pick-up surface that is picked-up during vacuum pick-up.

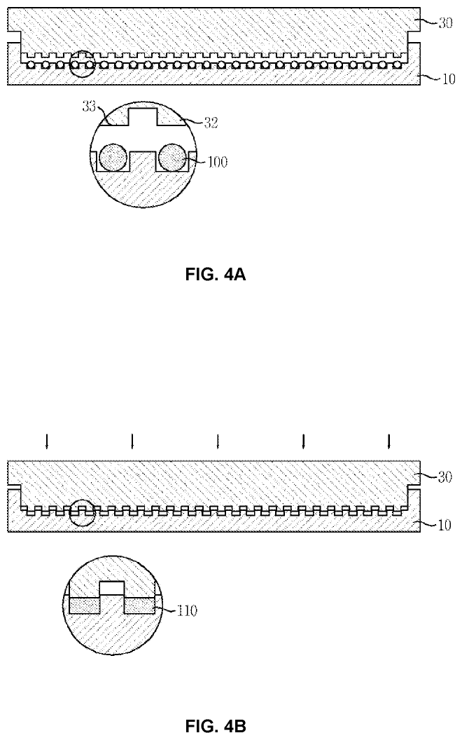

FIGS. 4A and 4B schematically illustrate a method for making a non-spherical solder ball according to another embodiment of the present disclosure.

As illustrated in FIG. 4A, a spherical solder ball 100 is inserted into an accommodation groove 12, and an instrument having a pressing cover 30 capable of pressing the spherical solder ball 100 from above an instrument 10 is prepared.

In this embodiment, a pressing protrusion 32 corresponding to the accommodation groove 12 of the instrument 10 protrudes from a bottom surface of the pressing cover 30 by assuming a case in which the spherical solder ball 100 has a volume less than a capacity of the accommodation groove 12. In a case in which the spherical solder ball 100 has a volume equal to or slightly greater than the capacity of the accommodation groove 12, the pressing protrusion 32 in not necessary, and the pressing cover 30 may have a flat bottom surface.

In this embodiment, a contact surface 33 of the pressing protrusion 32 is flat. In another embodiment, however, a contact surface 33 of a pressing protrusion 32 may be curved, and a non-spherical solder ball 110 having a different shape, e.g., an egg-shape, may be manufactured.

Preferably, each of the pressing cover 30 and the pressing protrusion 32 may be made of a material that is not attached with a softened solder ball when the spherical solder ball 100 is softened.

Thereafter, the spherical solder ball 100 is softened so that a shape is deformable even with weak force by applying heat to the instrument 10 or controlling a heating temperature when the spherical solder ball is heated.

Here, the softening represents a soft state before the spherical solder ball 100 is completely converted into a liquid phase by heating.

In this state, as illustrated in FIG. 4B, the pressing protrusion 32 is in contact with and presses the spherical solder ball 100 by descending of the pressing cover 30.

That is, as the spherical solder ball 100 is inserted into the accommodation groove 12 as illustrated in FIG. 4A, and then the pressing protrusion 32 is in contact with and presses the softened spherical solder ball 100 by the descending of the pressing cover 30 as illustrated in FIG. 4B, the spherical solder ball 100 may be spread smoothly with weak force and deformed into a shape corresponding to the accommodation groove 12.

As another making method, the spherical solder ball 100 may be softened and deformed by providing ultrasonic waves through the pressing protrusion 32 in a state in which the pressing protrusion 32 of the pressing cover 30 is in contact with and presses the spherical solder ball 100.

Thereafter, additional heat treatment may be performed depending on a shape of the deformed spherical solder ball 100 to further stabilize a structure or shape of the deformed spherical solder ball 100 as necessary.

Thereafter, the non-spherical solder ball 110 having a shape corresponding to that of the accommodation groove 12 is cooled and then withdrawn from the accommodation groove 12 and sorted according to a symmetry standard.

As described above, when the non-spherical solder ball 110 manufactured by softening and pressing the spherical solder ball 100 disposed in the accommodation groove 12 and the non-spherical solder ball 110 manufactured by melting the spherical solder ball 100 are compared with each other, the non-spherical solder balls 110 have advantages and disadvantages depending on different making methods.

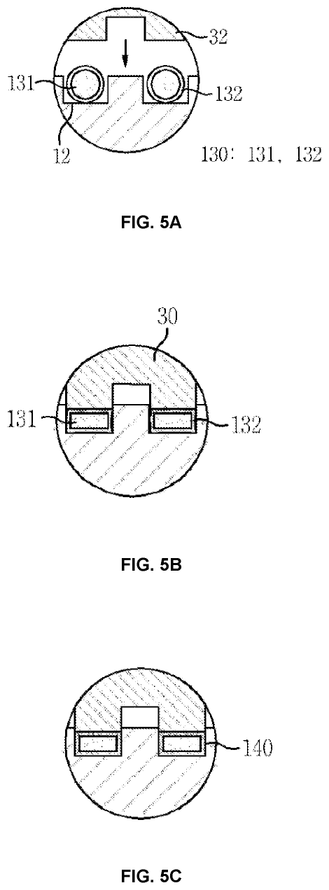

FIGS. 5A to 5C schematically illustrate a method for making a non-spherical solder ball according to another embodiment of the present disclosure.

In this embodiment, a spherical solder ball 130 may be a cored solder ball (CSB) having a structure in which a solder or solder alloy 132 is formed on a copper or polymer core 131 by plating.

The core 131 may be made of a metal having a melting point higher than that of the solder or solder alloy 132 and excellent mechanical elongation such as aluminum, aluminum alloy, copper, and copper alloy, and the CSB may be produced by plating nickel on the core 131 and then plating a solder or solder alloy thereon.

Also, the core 131 may be made of a polymer resin. In this case, the core 131 may have a melting point greater or less than that of the solder or solder alloy 132. Preferably, the core 131 has a melting point greater than that of the solder or solder alloy 132.

The spherical solder ball 130 is deformed to have a shape similar to that of the accommodation groove 12 by inserting the spherical solder ball 130 into the accommodation groove 12 and then applying great force by using the pressing protrusion 32 of the pressing cover 30.

That is, when the core 131 is made of a metal, the core 131 has a melting temperature that is extremely greater than that of the solder or solder alloy 132 formed on the core 131. Thus, the spherical solder ball 130 is firstly deformed into the shape of the accommodation groove 12 by mechanical pressing.

Thereafter, the plated solder or solder alloy is melted by heating the deformed spherical solder ball 130.

Referring to FIG. 5B, as the solder alloy 132 laminated on the core 131 during the above-described process is torn or broken according to the deformation caused by the pressing of the core 131, uniform lamination may not be performed.

Thus, as illustrated in FIG. 5C, the non-spherical solder ball having the solder or solder alloy 132 laminated on the core 131 with a constant thickness is manufactured and then sorted by melting the solder or solder alloy 132 laminated on the core 131 deformed into the shape of the accommodation groove 12 through heating, deforming the solder or solder alloy 132 into a shape corresponding to that of the accommodation groove 12, and then cooling the solder or solder alloy 132.

Preferably, the non-spherical solder ball may have a hexahedral shape having a height greater than a width thereof to easily correspond to a micro-pattern. However, the embodiment of the present disclosure is not limited thereto.

According to the present disclosure, the non-spherical solder balls may be mass-produced efficiently, uniformly and economically by inserting the solid spherical balls that are commercially available, widely used, uniform, and price-competitive into the accommodation grooves of the instrument and then processing the spherical balls by applying the heat, the pressure, or the combination thereof to the spherical balls.

Thus, the non-spherical solder balls produced during the mass production may have the same size and shape as each other within the range that is not deviated greatly from the deviations.

Also, the non-spherical solder balls have the uniform size, shape, and weight and are produced by the simple, easy, and economical making process by providing the non-spherical solder balls processed after the spherical solder balls are inserted into the accommodation grooves instead of using the solder alloy sheet or the liquid solder alloy.

Although the exemplary embodiment of the present invention has been shown and described above, various changes and modifications which can be understood by a person skilled in the art may also be made. Thus, the present invention should not be construed as being limited to only the foregoing embodiment, but be construed by the appended claims.

What is claimed is:

1. A method for making a non-spherical solder ball that mechanically and electrically connects an object by soldering, the method comprising:
preparing a plurality of spherical solder balls;
preparing a mold having a plurality of non-spherical accommodation grooves;
inserting the spherical solder balls into the non-spherical accommodation grooves;
deforming the spherical solder balls into a shape corresponding to that of each of the non-spherical accommodation grooves and making non-spherical solder balls by applying heat, a pressure, or a combination thereof to the spherical solder balls or the mold in the state in which the spherical solder balls are inserted into the non-spherical accommodation grooves;
withdrawing the non-spherical solder balls from the non-spherical accommodation grooves; and
sorting the withdrawn non-spherical solder balls according to a preset reference.

2. The method of claim 1, wherein the non-spherical solder ball has a shape formed only by a shape of the non-spherical accommodation groove or formed by combining the shape of the non-spherical accommodation groove with a shape of a cover configured to cover the mold.

3. The method of claim 2, wherein the heat, the pressure, or the combination thereof is applied to the mold, the cover, or the combination thereof.

4. The method of claim 2, wherein each of the mold and the cover is made of a metal material or a heat-resistant polymer material that is not attached to the non-spherical solder ball when the non-spherical solder ball is manufactured by the heating.

5. The method of claim 2, wherein the spherical solder ball melted by the heating is deformed by ultrasonic waves, vibration of a motor, or a pressure by the cover.

6. The method of claim 1, wherein the heating is performed at a temperature at which the spherical solder ball is softened or melted.

7. The method of claim 1, further comprising cooling the non-spherical solder ball when making the non-spherical solder ball by the heating.

8. The method of claim 1, wherein a shape of the non-spherical solder ball has a hemispherical, cylindrical or hexahedral shape different from that of the spherical solder ball.

9. A non-spherical solder ball manufactured by the method of claim 1, wherein the non-spherical solder ball is symmetrical in an upward and downward direction and a left and right direction.

10. The non-spherical solder ball of claim 9, wherein at least one surface of surfaces of the non-spherical solder ball forms a plane.

11. The non-spherical solder ball of claim 9, wherein the non-spherical solder ball is surface-mounted by vacuum pickup.

12. A method for making a non-spherical solder ball that mechanically and electrically connects an object by soldering, the method comprising:
inserting a spherical solder ball having a structure in which a solder or solder alloy is laminated on a spherical metal or polymer core into a non-spherical accommodation groove of an instrument;
deforming the spherical solder ball into a shape corresponding to that of the accommodation groove by applying physical force to the spherical solder ball;
melting the solder or solder alloy by heating the deformed spherical solder ball;
forming a non-spherical solder ball by cooling the melted solder or solder alloy; and
withdrawing the cooled non-spherical solder ball and sorting the withdrawn non-spherical solder ball according to a preset reference.
